(19) United States
(12) Patent Application Publication
(10) Pub. No.: US 2008/0285218 A1
(43) Pub. Date: Nov. 20, 2008

(54) Electronic device

(75) Inventor: Takashi Iijima, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki-shi (JP)

(21) Appl. No.: 12/219,628

(22) Filed: Jul. 24, 2008

Related U.S. Application Data
(63) Continuation of application No. PCT/JP2006/301191, filed on Jan. 26, 2006.

(51) Int. Cl. H05K 1/16; H05K 7/14; H01R 13/648

(52) U.S. Cl. 361/680; 361/748; 439/607

(57) ABSTRACT

The present relates to an electronic device represented by, for example, a personal computer and aims to reinforce a connector as well as suppress the increase in the number of parts. The electronic device includes: a motherboard 29; a USB connector 23 whose one side is secured to the motherboard 29 with its mating surface 231 pointing outward; and a support member 51 for supporting a woofer 25 which is larger than the USB connector 23, and which is disposed in a position adjacent to the USB connector 23; and the support member 51 further has a reinforcement section 512 for reinforcing the USB connector by adjoining the USB connector 23.

### TECHNICAL FIELD

The present invention relates to an electronic device represented by, for example, a personal computer.

### BACKGROUND ART

In recent years, a personal computer (hereinafter, it is abbreviated to PC) has become widespread not only in offices but also in households. As one example of this PC, a so-called notebook personal computer (hereinafter, it is abbreviated to notebook PC) has been known, which includes a main unit equipped with a keyboard on its upper surface and a display unit equipped with a display screen which can be opened and closed freely with respect to the main unit, and when the notebook PC is used, the display unit is opened to stand against the main unit, and when the notebook PC is not used, the display screen is folded so as to overlay the keyboard.

Also recently, a so-called tablet personal computer (hereinafter, it is abbreviated to tablet PC) has emerged, which is formed of one unit having the shape of board equipped with a display screen on its upper surface, and into which instruction is input either by bringing a pen near the display screen or by touching the screen with the pen and then by recognizing the approached or touched position.

Further, there has also emerged in recent years an electronic device which can be used as a notebook PC by standing its display unit, whose main unit and display unit are connected together via a biaxial connecting section that supports the units so as to open, close and rotate freely, and which can also be used as a tablet PC by overlaying the display unit on the main unit in a manner that the display screen is directed upward.

Miniaturization is also required for electronic devices in general such as PCs, and especially for the notebook PC and the tablet PC, the miniaturization and the slimming down is strongly requested because they are required to be highly portable. In recent years, the notebook PC or the like comes to incorporate advanced functionality that is not inferior to so-called desktop PCs and continues to incorporate higher functionality. Therefore, there is demand for realizing the miniaturization and the slimming down as well as maintaining high operability without falling behind the trend of incorporating such advanced functionality.

Meanwhile, the PC is provided with a connector for external communication, and the recent PCs are generally equipped with a USB connector adhered to the USB (Universal Serial Bus) standard. Also in the PCs, generally a speaker is either incorporated or externally attached (See Documents 1 and 2 listed below), and in order to realize advanced functionality of the notebook PC, the quality of sound is also an important factor and a fairly large speaker, for example, a woofer is required to be incorporated in the notebook PC.

Document 1: Japanese Patent Application Publication No. 2005-310001

Document 2: Japanese Patent Application Publication No. 2001-307799

When the miniaturization and the slimming down of electronic devices such as the notebook PC advances, a motherboard to which a connector for communication such as a USB connector or the like is attached becomes a thin board and the attachment itself tends to become fragile. However, the USB connector or the like may be inserted and extracted many times and they are subject to force applied from the side at the time of insertion and extraction. In order to prevent damages or the like from occurring even in such a case, it is necessary to have a structure that can endure the external force applied from the side by reinforcing the connector.

However, if such a reinforcing member is provided, the number of parts increases correspondingly, which is unfavorable in terms of cost, compactness and slimming down.

In view of the above circumstances, it is an object to provide an electronic device that can reinforce the connector as well as suppress the increase in the number of parts.

### DISCLOSURE OF THE INVENTION

An electronic device of the present invention achieving the above object, includes:

a board;

a connector whose one side is secured to the board and whose mating surface is directed outward; and

a support member disposed in a position adjacent to the connector and supporting an on-board component larger than the connector,

wherein the support member has a reinforcement section that reinforces the connector by adjoining the connector.

Here, the on-board component may be a woofer.

In the electronic device according to the present invention, since the support member that supports the on-board component such as the woofer adjoining the connector has a reinforcement section for reinforcing the connector, there is no need to provide an independent part for strengthening the connector and therefore it is possible to reinforce the connector and reduce the number of parts.

Here, it is desirable that the on-board component is supported by the support member via a cushion member interposed between the on-board component and the support member.

With this, when external force is applied to the connector, the external force is absorbed by the cushion member and thereby it is possible to prevent the on-board component from being affected by the external force. Furthermore, even when the external force is applied to the on-board component or when the on-board component itself vibrates, it is also possible to prevent the connector from being affected by the external force or the vibration.

Moreover, it is desirable that the support member including the reinforcement section is formed by sheet-metal working.

By sheet-metal working, the support member can be created at a low cost.

Furthermore, it is desirable that the reinforcement section includes a first board section touching an undersurface, opposite to the mating surface, of the connector; and a second board section and a third board section that stand at both ends of the first board section and touch two sides of the connector, the two sides adjoining both sides of the one side, secured to the motherboard, of the connector.

In this way, by holding the connector from three directions with the first to the third board sections, sufficient reinforcement can be accomplished.

Here, the connector may be a USB connector adhered to the USB standard.

The present invention can be suitably applied to the USB connectors.

Here, the USB is the abbreviation of Universal Serial Bus and is one of the standard for data transmission path connecting peripheral devices such as a keyboard, a mouse, a modem, a joystick and the like with a PC. In addition, this electronic device may have a main unit that houses the board, and the connector may be mounted in the main part so as to expose its mating surface at the side of the main unit. Also, this electronic device may include a keyboard on the upper face of the main unit and furthermore, may include a display unit equipped with a display screen, the display unit being openable and closable with respect to the main unit.

The present invention can be suitably applied to a tablet PC or a notebook PC, and since there are many cases when the connector on the main unit side is frequently inserted and extracted, the present invention is suitably applied to the connector on the main unit side.

Also when the present invention is applied to the notebook PC and the tablet PC, the on-board component may be a woofer that outputs sound outward from the undersurface of the main unit.

As described above, according to the present invention, it is possible to reinforce the connector while suppressing the increase in the number of parts.

### BRIEF DESCRIPTION OF THE DRAWINGS

FIG. 1 is an external perspective view of a notebook PC as one embodiment according to the present invention, when viewed diagonally from its front.

FIG. 2 is an external perspective view of the notebook PC as one embodiment of the present invention, when viewed from a different direction than that of FIG. 1.

FIG. 3 is a diagram showing the undersurface of the main unit.

FIG. 4 is a perspective view of the right side face of the notebook PC shown in FIGS. 1 to 3, when viewed diagonally from the upper face side of the main unit.

FIG. 5 is a perspective view of the right side face of the same notebook PC, when viewed diagonally from the undersurface side of the main unit.

FIGS. 6A and 6B are diagrams showing a support member that supports a woofer and the woofer, respectively.

FIG. 7 is a diagram showing a state in which the support member shown in FIG. 6A supports the woofer shown in FIG. 6B.

FIG. 8 is a diagram showing the state same as in FIG. 7, when viewed from the support member side.

FIG. 9 is a perspective view showing the main unit mounted only with the support member, by removing the woofer.

FIG. 10 is a diagram showing a state in which the main unit is further mounted with the woofer.

### BEST MODE FOR CARRYING OUT THE INVENTION

An embodiment of the present invention will be described below.

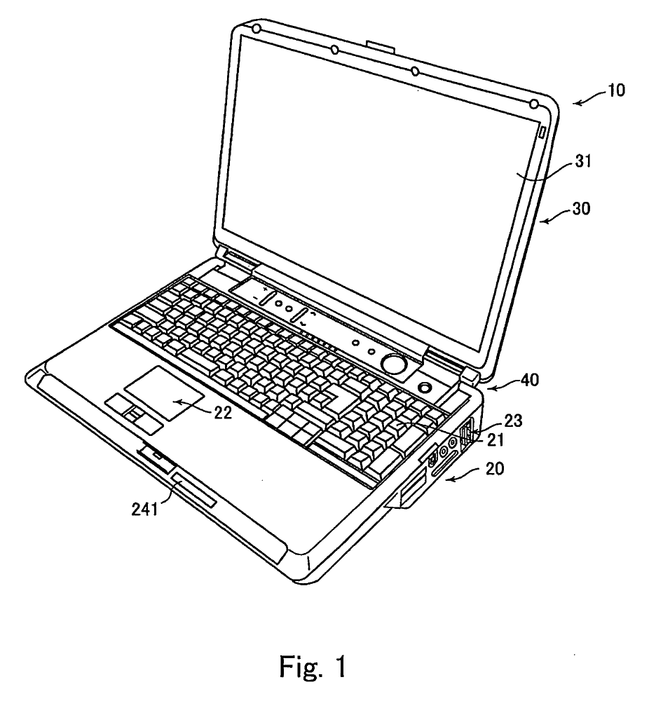

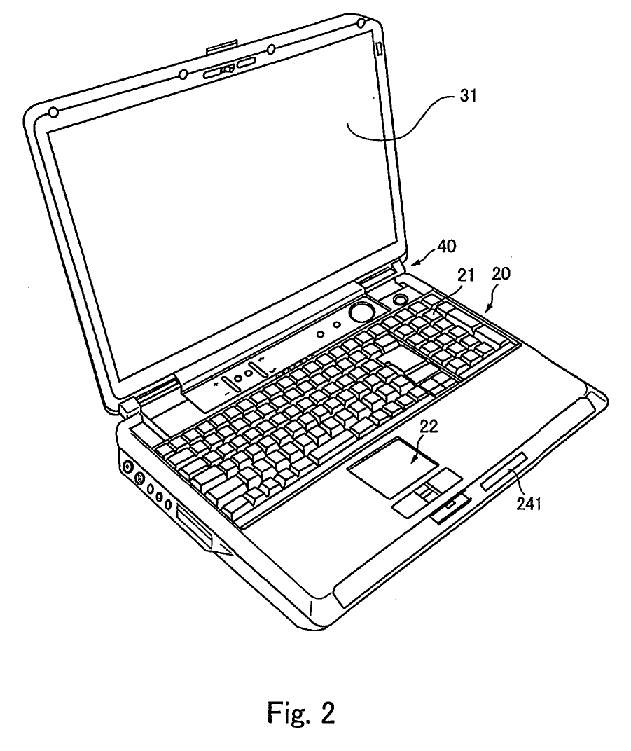

FIGS. 1 and 2 are external perspective views of the notebook PC as one embodiment of the present invention, when viewed diagonally from its front, each from different direction.

This notebook PC 10 includes two enclosures composed of a main unit 20 and a display unit 30. The display unit 30 is supported by a hinge section 40 so as to open and close freely with respect to the main unit 20.

The main unit 20 is equipped with a keyboard 21 and a track pad 22 or the like on its upper surface, and to the right side, a USB connector 23 which is an element to be described later in detail is disposed with its mating surface pointing outward. This main unit 20 incorporates a motherboard 29 on which various kinds of parts including this USB connector 23 are mounted, a hard disk drive unit, an optical disk drive unit, a battery unit and other various kinds of units within the case. Additionally this case is composed of an upper cover and a lower cover, and the motherboard 29 and the various kinds of units are housed within the lower cover, and above the lower cover, there is disposed the upper cover that covers them and has areas divided for housing the keyboard 21 and the track pad 22 by exposing them so as to be operable.

Moreover, this notebook PC 10 incorporates built-in TV receiving function, and in the front end of the main unit 20, a slot cover 241 is disposed which covers an opening of a card slot through which a B-CAS card, a kind of IC cards, can be inserted and removed freely. Here, the B-CAS card is the abbreviation of BS-Conditional Access Systems Card, which is an IC card in which key data for decoding encryption has been recorded, which is attached to a device (TV and tuner) for receiving digital broadcasting.

Furthermore, the display unit 30 has a large display screen 31 on its front.

Moreover, the hinge section 40 has such a structure that the display unit 30 is supported by the main unit 20 so that the display unit 30 can open and close freely with respect to the main unit 20.

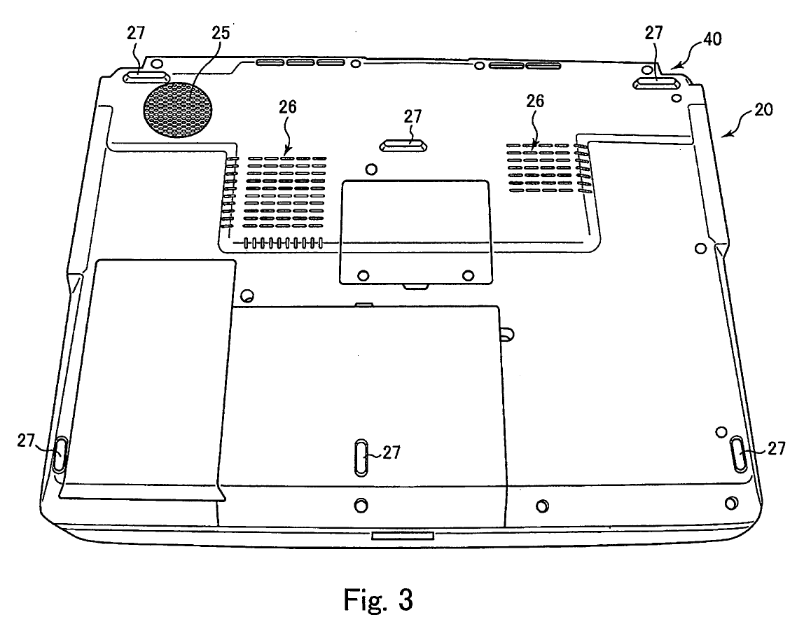

FIG. 3 is a diagram showing the undersurface of the main unit 20.

In a position near the hinge section 40 on the undersurface of this main unit 20, a woofer 25 can be seen. Also, in a position that is closer to the hinge section 40 side than the center of the main unit 20, air holes 26 for circulating air within the main unit are formed. This is because heat-producing parts such as a CPU and the like are disposed in the back of the main unit 20 in order to make the amount of heat produced in the back half of the main unit 20 become larger than the amount of heat produced in the front half thereof. Moreover, on the undersurface of this main unit 20, floor-standing pads 27 are provided in a manner that they protrude a little from the undersurface of the main unit 20 so as to prevent, when the main unit 20 is placed on the desk or the like, the woofer 25 and the air holes 26 from touching the surface of the desk.

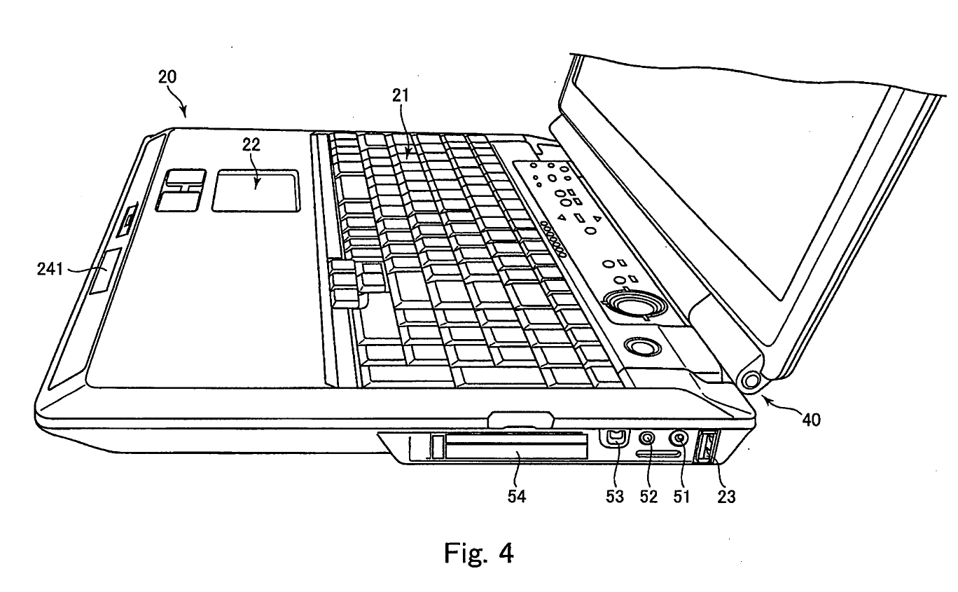

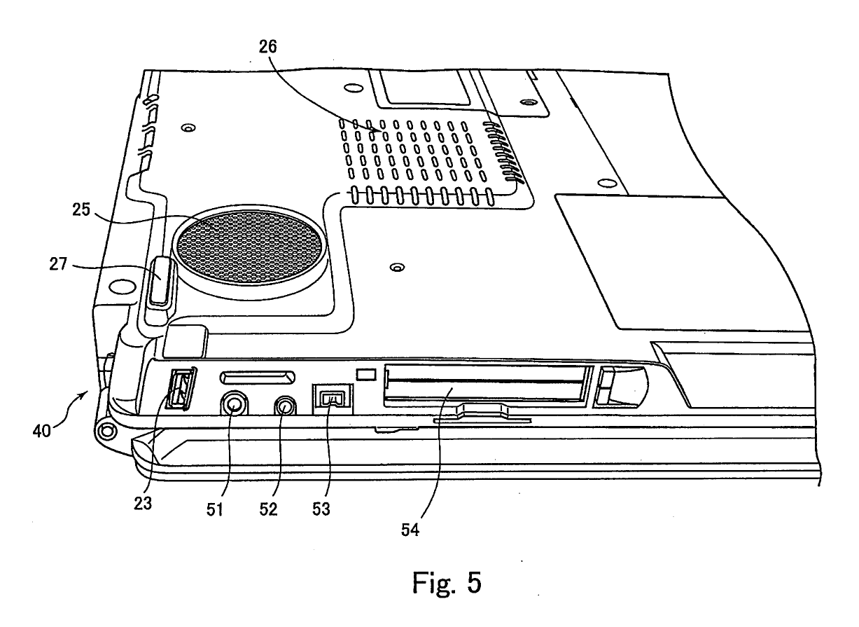

FIG. 4 is a perspective view of the right side face of the notebook PC shown in FIGS. 1 to 3, when viewed diagonally from the upper face side of the main unit. FIG. 5 is a perspective view of the right side face of the same notebook PC, when viewed diagonally from the undersurface side of the main unit.

On the right side face of the main unit 20, the previously described USB connector 23 and furthermore, a jack 51 for microphone, a jack 52 for headphone and a connector 53 adhered to the IEEE 1394 standard are lined up, and next to them, a slot 54 for a PC card slot is disposed in which a removable PC card can be inserted to be accessed. The jacks 51 and 52 are also mounted on the motherboard 29 in a manner similar to the USB connector 23.

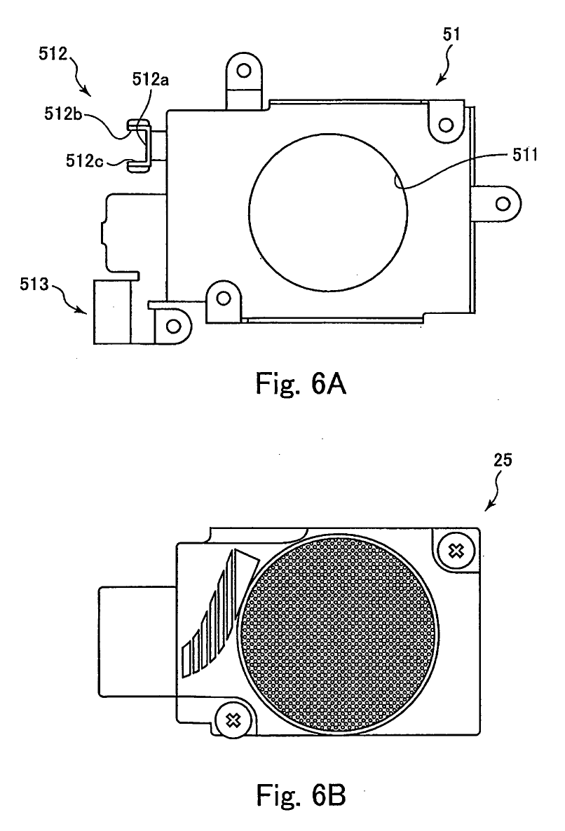

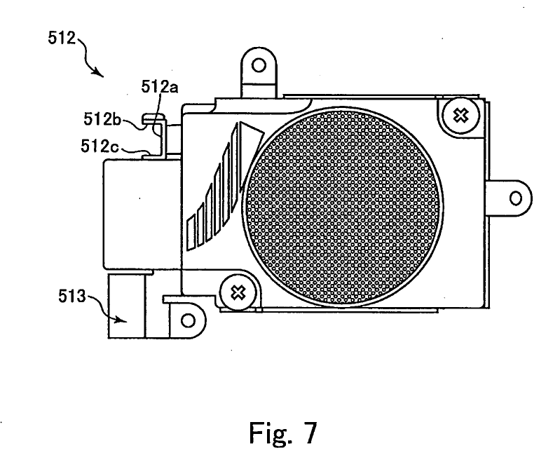

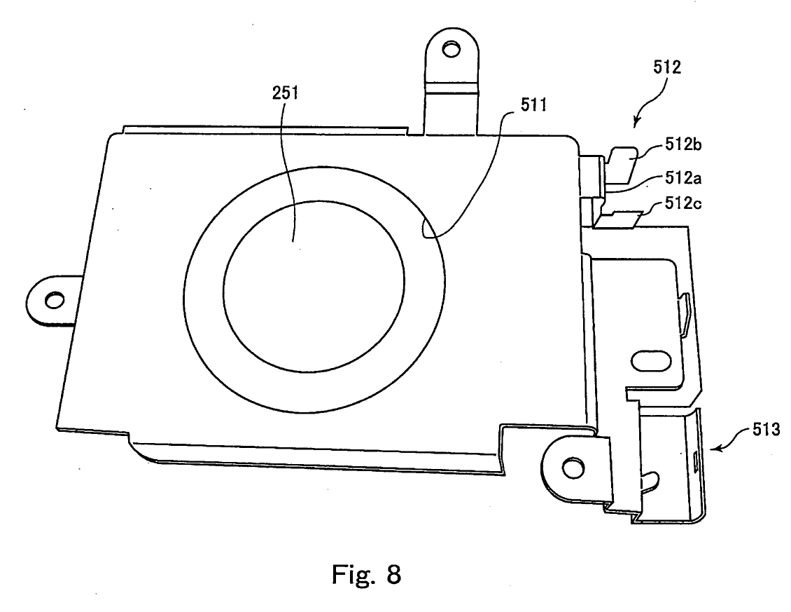

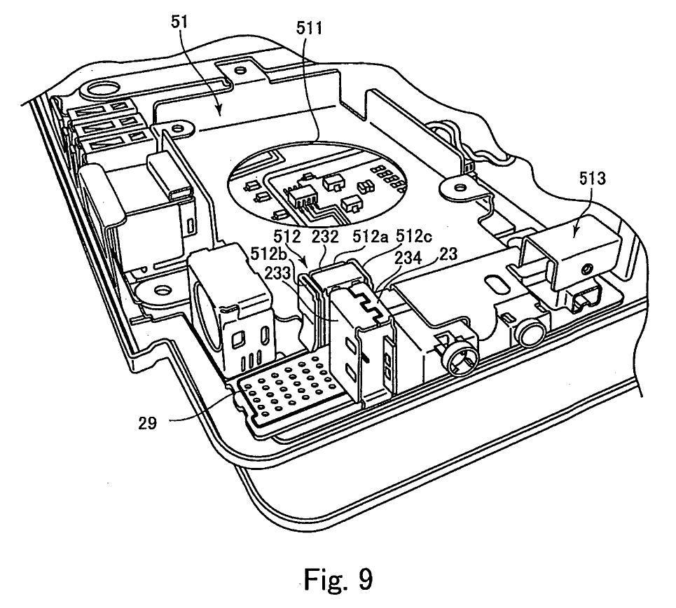

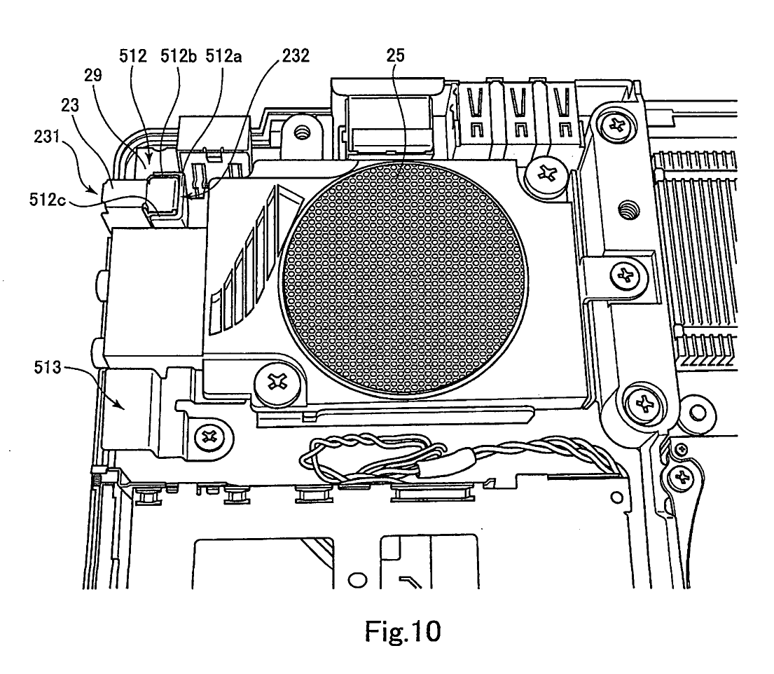

FIG. 6A is a diagram showing a support member that supports the woofer and FIG. 6B is a diagram showing the woofer. FIG. 7 is a diagram showing a state in which the support member shown in FIG. 6A supports the woofer shown in FIG. 6B. FIG. 8 is a diagram showing the state same as in FIG. 7, when viewed from the support member side. FIG. 9 is a perspective view showing the main unit mounted only with the support member, by removing the woofer. FIG. 10 is a diagram showing a state in which the main unit is further mounted with the woofer.

As shown in FIG. 6A, the support member 51 that supports the woofer 25 is formed by bending of sheet-metal working and a circular opening 511 through which a backside 251 of the woofer 25 can be seen is formed in the center (See FIG. 8). Also at the left side portion of this support member 51 in FIG. 6A, a USB connector reinforcement section 512 for reinforcing the USB connector 23 at the right side of the main unit (See FIGS. 4 and 5) and an IEEE 1394 connector reinforcement section 513 for reinforcing an IEEE 1394 connector 53 (See FIGS. 4 and 5) are formed.

Here, the USB connector 23 is secured to the motherboard 29 with its one side (See FIG. 9) and disposed with its mating surface pointing outward, and the USB connector reinforcement section 512 of the support member 51 has a structure that rigidly reinforces the USB connector 23 from three directions, by having a first board section 512a touching an undersurface 232 opposite to a mating surface 231 of the USB connector 23; and a second and a third board sections 512b, 512c that stand at both ends of the first board section 512a and touch two sides 233, 234 adjoining both sides of the one side, secured to the motherboard 29, of the USB connector 23.

With this structure, even if sideway force is applied to the USB connector 23 when a connector that engages with the USB connector 23 is either inserted or extracted, it is possible to prevent occurrence of bending or separation between the motherboard 29 on which the USB connector 23 has been secured and the USB connector 23, and the original function of the USB connector 23 can be maintained for a long time.

Moreover, the IEEE 1394 connector reinforcement section 513 that reinforces the IEEE 1394 connector 53 strengthens the IEEE 1394 connector 53 by covering it from the above. With this, in a manner similar to the USB connector 23, it is possible to prevent the IEEE 1394 connector 53 from being bent or the like by external forces, and thus its original function can be maintained for a long time.

Furthermore, on the support member 51, a cushion member that is not shown (here, it is a rubber board, specifically) is laid and the woofer 25 is placed on it and secured.

In this way, for one thing, it is possible to prevent the vibration from being conveyed to the other parts at the time of outputting the sound from the woofer 25, and for another thing, it is possible to prevent a bad influence from being exerted on the securing of the woofer due to the conveyance of careless force applied at the time of the insertion and extraction of the USB connector 23.

Incidentally, although the description has been made by the example of the notebook PC, the present invention can also be applied to a computer other than the notebook PC and furthermore, to electronic devices in general.

What is claimed is:

1. An electronic device comprising:
a board;
a connector whose one side is secured to the board and whose mating surface is directed outward; and
a support member disposed in a position adjacent to the connector and supporting an on-board component larger than the connector,
wherein the support member has a reinforcement section that reinforces the connector by adjoining the connector.

2. The electronic device according to claim 1, wherein the on-board component is a woofer.

3. The electronic device according to claim 1, wherein the on-board component is supported by the support member via a cushion member interposed between the on-board component and the support member.

4. The electronic device according to claim 1, wherein the support member including the reinforcement section is formed by sheet-metal working.

5. The electronic device according to claim 1, wherein the reinforcement section comprises a first board section touching an undersurface, opposite to the mating surface, of the connector; and a second board section and a third board section that stand at both ends of the first board section and touch two sides of the connector, the two sides adjoining both sides of the one side, secured to the motherboard, of the connector.

6. The electronic device according to claim 1, wherein the connector is a USB connector adhered to the USB standard.

7. The electronic device according to claim 1, wherein the electronic device has a main unit housing the board, and
the connector is mounted in the main unit with the mating surface thereof exposed outward at the side of the main unit.

8. The electronic device according to claim 7, wherein the on-board component is a woofer that outputs sound outward from the undersurface of the main unit.

9. The electronic device according to claim 7, wherein the main unit comprises a keyboard on an upper face thereof and a display unit equipped with a display screen, the display unit being openable and closable with respect to the main unit.

10. A support member used to mount a part in an electronic device equipped with a board and a connector whose one side is secured to the board and whose mating surface is directed outward, wherein:
the support member is disposed in a position adjacent to the connector and supports an on-board component larger than the connector, the support member having a reinforcement section that reinforces the connector by adjoining the connector.

11. The support member according to claim 10, wherein the on-board component is a woofer.

12. The support member according to claim 10, wherein the on-board component is supported by the support member via a cushion member interposed between the on-board component and the support member.

13. The support member according to claim 10, wherein the support member including the reinforcement section is formed by sheet-metal working.

14. The support member according to claim 10, wherein the reinforcement section comprises a first board section touching an undersurface, opposite to the mating surface, of the connector; and a second board section and a third board section that stand at both ends of the first board section and touch two sides of the connector, the two sides adjoining both sides of the one side, secured to the motherboard, of the connector.

15. The support member according to claim 10, wherein the connector is a USB connector adhered to the USB standard.
